(19) United States
(12) Patent Application Publication
(10) Pub. No.: US 2024/0235527 A1
(43) Pub. Date: Jul. 11, 2024

(54) ACOUSTIC WAVE FILTER

(71) Applicant: Murata Manufacturing Co., Ltd., Nagaokakyo-shi (JP)

(72) Inventor: Norikazu TAMAOKI, Nagaokakyo-shi (JP)

(21) Appl. No.: 18/391,745

(22) Filed: Dec. 21, 2023

(30) Foreign Application Priority Data
Jan. 5, 2023 (JP) 2023-000713

(51) Int. Cl. H03H 9/64; H03H 9/02

(52) U.S. Cl. CPC H03H 9/6489; H03H 9/02992; H03H 9/6483

(57) ABSTRACT

An acoustic wave filter includes a filter circuit and an additional circuit including IDTs and a reflector. A first excitation portion of one of the IDTs is adjacent to the reflector. An outermost IDT includes ((N/2)+1) electrode fingers when a total number N of the electrode fingers included in the outermost IDT is an even number, or the outermost IDT includes ((N+1)/2) electrode fingers when the total number N is an odd number. A second excitation portion of the one of the IDTs includes two or more electrode fingers, except the electrode fingers of the first excitation portion. Assuming an average arrangement pitch of the electrode fingers included in the first excitation portion is px and an average arrangement pitch of reflection electrode fingers is pr, pr/px has a value in a range from about 0.5 to about 0.97 or a range from about 1.15 to about 2.0.

### CROSS REFERENCE TO RELATED APPLICATIONS

This application claims the benefit of priority to Japanese Patent Application No. 2023-000713 filed on Jan. 5, 2023. The entire contents of this application are hereby incorporated herein by reference.

### BACKGROUND OF THE INVENTION

### 1. Field of the Invention

The present invention relates to an acoustic wave filter.

### 2. Description of the Related Art

Conventionally, an acoustic wave filter including a filter circuit and an additional circuit connected in parallel to the filter circuit has been known. In Japanese Unexamined Patent Application Publication No. 2016-220263, there is disclosed a branching filter including a transmission filter connected between an antenna terminal and a transmission terminal, a reception filter connected between the antenna terminal and a reception terminal, and an acoustic wave element having one end connected to a path between the antenna terminal and the transmission terminal and having the other end connected to a path between the antenna terminal and the reception terminal. The acoustic wave element is an element to convert a phase of a transmission signal, inputted into the transmission terminal, into an opposite phase and is provided with a reflector.

### SUMMARY OF THE INVENTION

Improvement in Q-value can be achieved by providing a reflector for an acoustic wave element, for instance. However, an increase in Q-value may cause unnecessary resonance of the acoustic wave element and the occurrence of excitation waves in a band out of a pass band of the acoustic wave filter. A problem is caused in this case in that it is impossible to ensure attenuation characteristics in the band out of the pass band.

Example embodiments of the present invention provide acoustic wave filters that each reduce or prevent the occurrence of excitation waves in a band out of the pass band.

An acoustic wave filter according to an aspect of an example embodiment of the present invention includes a plurality of input-output terminals, a filter circuit in a first path linking the plurality of input-output terminals, and an additional circuit in a second path connected in parallel to at least a portion of the first path, in which the additional circuit includes a resonator including a plurality of interdigital transducers (IDTs) and a reflector, the plurality of IDTs are arranged along a first direction, the IDTs each include a plurality of electrode fingers extending in a second direction intersecting with the first direction and arranged along the first direction, the reflector is adjacent to an outermost IDT that is located in an outermost side portion of the plurality of IDTs with respect to the first direction and includes a plurality of reflection electrode fingers extending in the second direction and arranged along the first direction, the outermost IDT includes a first excitation portion and a second excitation portion, the first excitation portion is adjacent to the reflector in the first direction, the outermost IDT includes ((N/2)+1) electrode fingers when a total number N of the electrode fingers included in the outermost IDT is an even number, or the outermost IDT includes ((N+1)/2) electrode fingers when the total number N is an odd number, the second excitation portion is on an opposite side to the reflector as seen from the first excitation portion in the first direction and includes two or more electrode fingers, except the electrode fingers of the first excitation portion, among the plurality of electrode fingers included in the outermost IDT, and assuming an average arrangement pitch of the electrode fingers included in the first excitation portion in the first direction is px and an average arrangement pitch of the plurality of reflection electrode fingers in the first direction is pr, pr/px has a value in a range from about 0.5 to about 0.97 or a range from about 1.15 to about 2.0.

According to acoustic wave filters of example embodiments of the present invention, the occurrence of excitation waves in a band out of a pass band can be reduced or prevented.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a diagram illustrating an acoustic wave filter according to an example embodiment of the present invention and circuit configurations of a filter circuit and an additional circuit that are included in the acoustic wave filter.

FIG. 2 is a diagram schematically illustrating an acoustic coupling resonator included in the additional circuit.

FIG. 3 is a diagram illustrating average arrangement pitches of electrode fingers of first excitation portions and second excitation portions of IDTs included in the acoustic coupling resonator and an average arrangement pitch of reflection electrode fingers of reflectors.

FIG. 4 is a diagram illustrating an example of the average arrangement pitches of the electrode fingers of the first excitation portions and the second excitation portions and the average arrangement pitch of the reflection electrode fingers of the reflectors.

FIG. 5 is a diagram illustrating bandpass characteristics of acoustic wave filters of comparative examples 1, 2, and 3 and working example 1.

FIG. 6 is a diagram illustrating a relationship between arrangement pitch ratios that are ratios of the average arrangement pitch of the electrode fingers of the first excitation portions to the average arrangement pitch of the reflection electrode fingers of the reflector and amplitudes of excitation waves of a resonant mode that occur in a gap between the IDTs of the acoustic coupling resonator.

FIG. 7 is a diagram illustrating bandpass characteristics of acoustic wave filters of comparative examples 4, 5, and 6 and working examples 2 and 3.

FIG. 8 is a diagram illustrating a relationship between the arrangement pitch ratios that are the ratios of the average arrangement pitch of the electrode fingers of the first excitation portions to the average arrangement pitch of the reflection electrode fingers of the reflectors and amplitudes of excitation waves of a resonant mode that occur due to acoustic coupling in the acoustic coupling resonator.

### DETAILED DESCRIPTION OF THE EXAMPLE EMBODIMENTS

Hereinbelow, example embodiments of the present invention will be described in detail with reference to the example embodiments and the drawings. Incidentally, the example embodiments that will be described below each represent a non-limiting comprehensive or specific example. Numerical values, shapes, materials, components, placement and connection modes of the components, and the like that will be designated in the following example embodiments each represent an example and are not intended to limit the present invention. Further, sizes of components illustrated in the drawings or ratios of the sizes are not necessarily strict. In the drawings, further, substantially identical configurations are provided with identical reference characters and duplicated description may be omitted or simplified. Further, the term “connected” in the following example embodiments encompasses not only direct connection but also electrical connection with another element or the like interposed therebetween.

### EXAMPLE EMBODIMENTS

### Configurations of Acoustic Wave Filter

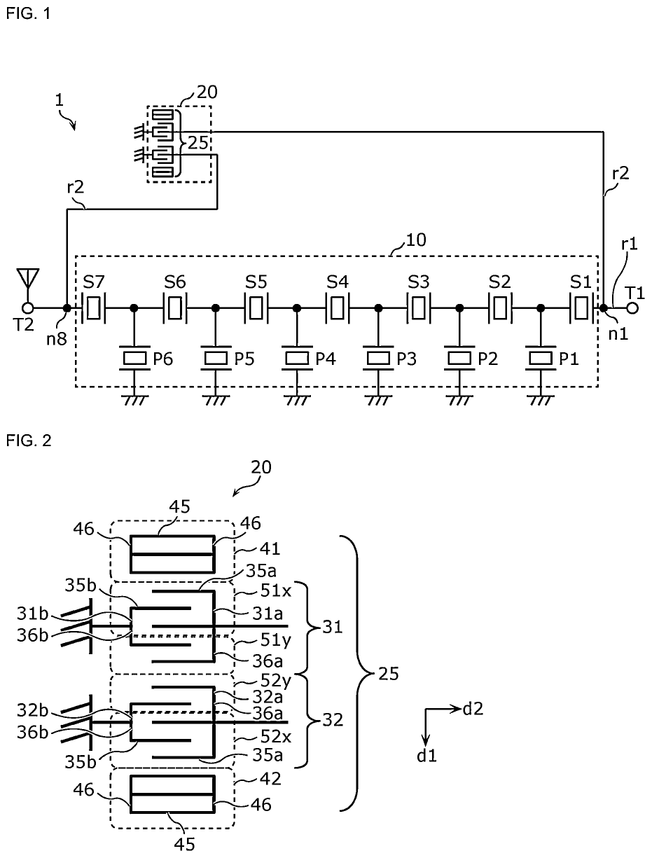

Configurations of an acoustic wave filter according to an example embodiment will be described with reference to FIG. 1.

FIG. 1 is a diagram illustrating an acoustic wave filter 1 according to the present example embodiment and circuit configurations of a filter circuit 10 and an additional circuit 20 that are included in the acoustic wave filter 1.

The acoustic wave filter 1 is a transmitting and receiving filter from and into which high-frequency signals are outputted and inputted, for instance. For the acoustic wave filter 1, characteristics in which passage of frequencies in an intrinsic band is allowed and in which frequencies out of a pass band are attenuated are demanded.

As illustrated in FIG. 1, the acoustic wave filter 1 includes the filter circuit 10, the additional circuit 20, an input-output terminal T1, and an input-output terminal T2.

The input-output terminal T1 is a terminal from and into which high-frequency signals are outputted and inputted. The input-output terminal T1 is connected to a signal processing circuit (not illustrated) with an amplifier circuit or the like (not illustrated) interposed therebetween, for instance.

The input-output terminal T2 is a terminal from and into which high-frequency signals are outputted and inputted. The input-output terminal T2 is connected to an antenna element, for instance.

The filter circuit 10 is a filter circuit that has a first frequency band, defined by a telecommunications standard, as the pass band. The first frequency band is Band41 (from 2496 MHZ to 2690 MHz inclusive), for instance. The filter circuit 10 is provided in a first path r1 linking the input-output terminal T1 and the input-output terminal T2.

As illustrated in FIG. 1, the filter circuit 10 includes serial arm resonators S1, S2, S3, S4, S5, S6, S7 and parallel arm resonators P1, P2, P3, P4, P5, P6 that are acoustic wave resonators.

The serial arm resonators S1 to S7 are located on the first path r1 linking the input-output terminal T1 and the input-output terminal T2. The serial arm resonators S1 to S7 are connected in series in order of mention from the input-output terminal T1 toward the input-output terminal T2.

The parallel arm resonators P1 to P6 are connected in parallel to one another on paths linking nodes between the serial arm resonators S1 to S7 and ground (reference terminals). Specifically, the parallel arm resonator P1 that is the nearest to the input-output terminal T1 of the parallel arm resonators P1 to P6 has one end connected to the node between the serial arm resonators S1 and S2 and has the other end connected to the ground. The parallel arm resonator P2 has one end connected to the node between the serial arm resonators S2 and S3 and has the other end connected to the ground. The parallel arm resonator P3 has one end connected to the node between the serial arm resonators S3 and S4 and has the other end connected to the ground. The parallel arm resonator P4 has one end connected to the node between the serial arm resonators S4 and S5 and has the other end connected to the ground. The parallel arm resonator P5 has one end connected to the node between the serial arm resonators S5 and S6 and has the other end connected to the ground. The parallel arm resonator P6 has one end connected to the node between the serial arm resonators S6 and S7 and has the other end connected to the ground.

Thus, the filter circuit 10 has a ladder filter structure made of the seven serial arm resonators S1 to S7 located on the first path r1 and the six parallel arm resonators P1 to P6 located on the paths linking the first path r1 and the ground.

Incidentally, the numbers of the serial arm resonators and the parallel arm resonators included in the filter circuit 10 are not limited to 7 or 6 and it is sufficient if one or more serial arm resonators and one or more parallel arm resonators exist. Further, the other ends of some parallel arm resonators among the plurality of parallel arm resonators may be made common and connected to the ground.

The additional circuit 20 illustrated in FIG. 1 is a cancel circuit that includes a cancellation component having an opposite phase and the same amplitude to and as the filter circuit 10 in order to improve attenuation characteristics of the filter circuit 10 out of the pass band.

The additional circuit 20 is provided in a second path r2 connected in parallel to at least a portion of the first path r1. The additional circuit 20 is connected to a plurality of nodes on the first path r1, for instance.

The additional circuit 20 includes an acoustic coupling resonator 25 including a plurality of interdigital transducers (IDTs) 31 and 32. The IDT 31 of the plurality of IDTs 31, 32 is connected to the first path r1 on a side of the input-output terminal T1 as seen from the acoustic coupling resonator 25, specifically, to a node n1 between the input-output terminal T1 and the serial arm resonator S1. The IDT 32 is connected to the first path r1 on a side of the input-output terminal T2 as seen from the acoustic coupling resonator 25, specifically, to a node n8 between the serial arm resonator S7 and the input-output terminal T2. In other words, the IDT 31 is connected to the first path r1 on the side of the input-output terminal T1 as seen from the serial arm resonators S1 to S7 connected in parallel to the acoustic coupling resonator 25 and the IDT 32 is connected to the first path r1 on the side of the input-output terminal T2 as seen from the serial arm resonators S1 to S7.

### Configurations of Additional Circuit

Configurations of the additional circuit 20 will be described with reference to FIG. 2.

FIG. 2 is a diagram schematically illustrating the acoustic coupling resonator 25 included in the additional circuit 20.

As illustrated in FIG. 2, the acoustic coupling resonator 25 includes the plurality of IDTs 31 and 32 and a plurality of reflectors 41 and 42. The acoustic coupling resonator 25 configures a longitudinally coupled resonator.

The acoustic coupling resonator 25 is made of a surface acoustic wave (SAW) resonator, for instance. The acoustic coupling resonator 25 includes a piezoelectric substrate, an electrode layer configuring IDT electrodes and reflector electrodes provided on the piezoelectric substrate, and a dielectric layer that is provided on the piezoelectric substrate so as to cover the electrode layer.

The piezoelectric substrate has a structure in which SiN, SiO₂, and LiTaO₃ are stacked in this order on a silicon substrate. A thickness of SiN is about 50 nm, a film thickness of SiO₂ is about 400 nm, and a film thickness of LiTaO₃ is about 300 nm, for instance. The electrode layer has a structure in which Ti, AlCu, and Ti are stacked in order of mention from a side of the piezoelectric substrate and respective thicknesses of those are about 18 nm, about 100 nm, and about 4 nm, for instance. The dielectric layer includes SiO₂ and has a thickness of about 30 nm, for instance.

The plurality of IDTs 31, 32 are located along a first direction d1 parallel to a principal surface of the piezoelectric substrate. The IDT 31 includes a first comb-shaped electrode 31a and a second comb-shaped electrode 31b that form a pair. The IDT 32 includes a first comb-shaped electrode 32a and a second comb-shaped electrode 32b that form a pair.

The first comb-shaped electrodes 31a, 32a each include a busbar electrode 36a extending in the first direction d1 and a plurality of electrode fingers 35a connected to the busbar electrode 36a and extending in a second direction d2 orthogonal to the first direction d1. The busbar electrode 36a connects one ends of the plurality of electrode fingers 35a.

The second comb-shaped electrodes 31b, 32b each include a busbar electrode 36b extending in the first direction d1 and a plurality of electrode fingers 35b connected to the busbar electrode 36b and extending in the second direction d2. The busbar electrode 36b connects one ends of the plurality of electrode fingers 35b. The plurality of electrode fingers 35a and 35b are interdigitated into each other in the second direction d2 and are located in parallel to each other.

The first comb-shaped electrodes 31a, 32a are connected to signal wiring on the second path r2 and the second comb-shaped electrodes 31b, 32b are connected to the ground. That is, the busbar electrode 36a and the electrode fingers 35a are set at a signal potential and the busbar electrode 36b and the electrode fingers 35b are set at a ground potential. Hereinbelow, both of the electrode fingers 35a and the electrode fingers 35b may be referred to and designated as electrode fingers 35.

The reflector 41 is located adjacent to the outermost IDT 31 that is located in an outermost side portion of the plurality of IDTs 31, 32 with respect to the first direction d1. The reflector 42 is located adjacent to the outermost IDT 32 that is located in an outermost side portion of the plurality of IDTs 31, 32 with respect to the first direction d1. That is, the plurality of reflectors 41, 42 are located in both outer side portions out of the IDTs 31, 32 with respect to the first direction d1 so that the plurality of IDTs 31, 32 are interposed therebetween.

The reflectors 41, 42 each include a plurality of reflection electrode fingers 45 and a plurality of reflection busbars 46. The plurality of reflection electrode fingers 45 extend in the second direction d2 and are arranged along the first direction d1. The reflection busbars 46 each connect one ends or the other ends of the plurality of reflection electrode fingers 45 and are located so as to extend in the first direction d1.

As illustrated in FIG. 2, the IDT 31 includes a first excitation portion 51x and a second excitation portion 51y and the IDT 32 includes a first excitation portion 52x and a second excitation portion 52y. The first excitation portions 51x, 52x are portions to generate the cancellation component having the opposite phase and the same amplitude to and as the filter circuit 10, as a primary purpose of the additional circuit 20. The second excitation portions 51y, 52y are narrow pitch portions to reduce or prevent too strong excitation of the first excitation portions 51x, 52x.

The first excitation portion 51x of the IDT 31 is located adjacent to the reflector 41 in the first direction d1. The first excitation portion 51x has more electrode fingers than a half of the plurality of electrode fingers 35 included in the outermost IDT 31. More specifically, assuming a total number of the electrode fingers included in the outermost IDT 31 is defined as N, the first excitation portion 51x includes ((N/2)+1) number of electrode fingers when N is an even number or includes ((N+1)/2) number of electrode fingers when N is an odd number. The first excitation portion 51x may have the number of pairs that is 60% or more of the number of pairs included in the outermost IDT 31.

The second excitation portion 51y of the IDT 31 is located on an opposite side to the reflector 41 as seen from the first excitation portion 51x in the first direction d1. The second excitation portion 51y includes two or more electrode fingers, except the electrode fingers of the first excitation portion 51x, among the plurality of electrode fingers included in the outermost IDT 31. The number of the electrode fingers 35 and the number of pairs thereof in the second excitation portion 51y are smaller than the respective numbers in the first excitation portion 51x.

The first excitation portion 52x of the IDT 32 is located adjacent to the reflector 42 in the first direction d1. The first excitation portion 52x has more electrode fingers than a half of the plurality of electrode fingers 35 included in the outermost IDT 32. More specifically, assuming a total number of the electrode fingers included in the outermost IDT 32 is defined as N, the first excitation portion 52x includes ((N/2)+1) number of electrode fingers when N is an even number or includes ((N+1)/2) number of electrode fingers when N is an odd number. The first excitation portion 52x may have the number of pairs that is 60% or more of the number of pairs included in the outermost IDT 32.

The second excitation portion 52y of the IDT 32 is located on an opposite side to the reflector 42 as seen from the first excitation portion 52x in the first direction d1. The second excitation portion 52y includes two or more electrode fingers, except the electrode fingers of the first excitation portion 52x, among the plurality of electrode fingers 35 included in the outermost IDT 32. The number of the electrode fingers 35 and the number of pairs thereof in the second excitation portion 52y are smaller than the respective numbers in the first excitation portion 52x.

In the present example embodiment, an arrangement pitch of the electrode fingers 35 included in the first excitation portions 51x, 52x and an arrangement pitch of the reflection electrode fingers 45 included in the reflectors 41, 42 have a relationship that will be described below.

Specifically, assuming an average arrangement pitch of the electrode fingers 35 included in the first excitation portion 51x of the IDT 31 in the first direction d1 is defined as px and assuming an average arrangement pitch of the reflection electrode fingers 45 included in the reflector 41 in the first direction d1 is defined as pr, an arrangement pitch ratio (pr/px) that is a ratio of pr to px has a value in a range from about 0.5 to about 0.97 or a range from about 1.15 to about 2.0, for example.

Similarly, assuming an average arrangement pitch of the electrode fingers 35 included in the first excitation portion 52x of the IDT 32 in the first direction d1 is defined as px and assuming an average arrangement pitch of the reflection electrode fingers 45 included in the reflector 42 in the first direction d1 is defined as pr, the arrangement pitch ratio (pr/px) has a value in a range from about 0.5 to about 0.97 or a range from about 1.15 to about 2.0, for example.

Thus, the occurrence of excitation waves in a band out of the pass band can be reduced or prevented by setting of the arrangement pitch ratio (pr/px) that is the ratio of pr to px in the range from about 0.5 to about 0.97 or the range from about 1.15 to about 2.0, for example. The numerical ranges will be described later.

Incidentally, assuming an average arrangement pitch of the electrode fingers 35 included in the second excitation portion 51y in the first direction d1 is defined as py, the present example embodiment has a relationship of px>py. That is, the second excitation portion 51y has a narrower pitch as a distance between the electrode fingers 35 than the first excitation portion 51x. Further, provided an average arrangement pitch of the electrode fingers 35 included in the second excitation portion 52y in the first direction d1 is defined as py, the present example embodiment has a relationship of px>py. That is, the second excitation portion 52y has a narrower pitch as a distance between the electrode fingers 35 than the first excitation portion 52x.

### Method of Finding Arrangement Pitch

A method of finding the average arrangement pitches px, py and the average arrangement pitch pr will be described.

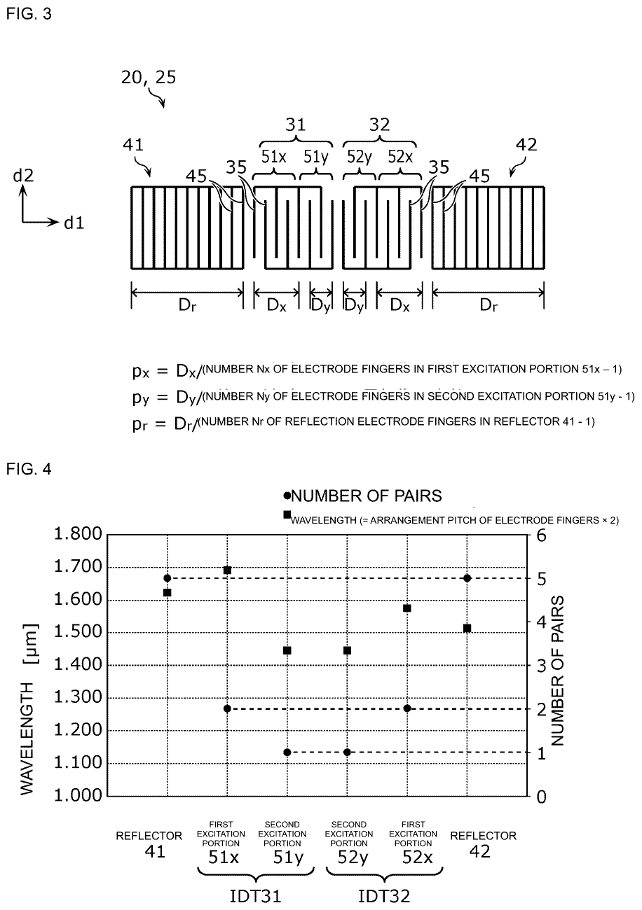

FIG. 3 is a diagram illustrating the arrangement pitches of the electrode fingers 35 of the first excitation portions 51x, 52x and the second excitation portions 51y, 52y of the IDTs 31, 32 included in the acoustic coupling resonator 25 and the arrangement pitch of the reflection electrode fingers 45 of the reflectors 41, 42.

The arrangement pitch of the electrode fingers 35 of the first excitation portion 51x (or 52x) refers to a center-to-center distance between the electrode fingers adjoining in the first direction d1 in the plurality of electrode fingers 35 included in the IDT 31 (or 32). All the arrangement pitches of the plurality of electrode fingers 35 in the first excitation portion 51x (or 52x) may be identical or some or all of the arrangement pitches may be different. Hereinbelow, a distance between centers of two electrode fingers in the first direction d1 may be simply referred to as “center-to-center distance”.

The average arrangement pitch px of the electrode fingers 35 of the first excitation portion 51x is derived as follows. A total number of the electrode fingers included in the first excitation portion 51x is defined as Nx, for instance. Further, the center-to-center distance between the electrode finger located at one end of the first excitation portion 51x in the first direction d1 and the electrode finger located at the other end thereof is defined as Dx. Then, the average arrangement pitch px can be represented by an equation px=Dx/(Nx−1). Incidentally, (Nx−1) may be conceived as a total number of gaps between adjoining electrode fingers in the first excitation portion 51x. The average arrangement pitch px of the electrode fingers 35 of the first excitation portion 52x of the IDT 32 is similarly derived as well.

The arrangement pitch of the electrode fingers of the second excitation portion 51y (or 52y) refers to a center-to-center distance between the electrode fingers adjoining in the first direction d1 in the plurality of electrode fingers 35 included in the IDT 31 (or 32). All the arrangement pitches of the plurality of electrode fingers 35 in the second excitation portion 51y (or 52y) may be identical or some or all of the arrangement pitches may be different.

The average arrangement pitch py of the electrode fingers 35 of the second excitation portion 51y is derived as follows. A total number of the electrode fingers included in the second excitation portion 51y is defined as Ny, for instance. Further, the center-to-center distance between the electrode finger located at one end of the second excitation portion 51y in the first direction d1 and the electrode finger located at the other end thereof is defined as Dy. Then, the average arrangement pitch py can be represented by an equation py=Dy/(Ny−1). Incidentally, (Ny−1) may be conceived as a total number of gaps between adjoining electrode fingers in the second excitation portion 51y. The average arrangement pitch py of the electrode fingers 35 of the second excitation portion 52y of the IDT 32 is similarly derived as well.

The arrangement pitches of the reflection electrode fingers 45 of the reflectors 41, 42 refer to center-to-center distances between the reflection electrode fingers adjoining in the first direction d1 in the plurality of reflection electrode fingers 45 included in the respective reflectors 41, 42. All the arrangement pitches of the plurality of reflection electrode fingers 45 in the reflectors 41, 42 may be identical or some or all of the arrangement pitches may be different.

The average arrangement pitch pr of the reflection electrode fingers 45 of the reflector 41 is derived as follows. A total number of the reflection electrode fingers 45 included in the reflector 41 is defined as Nr, for instance. Further, the center-to-center distance between the reflection electrode finger located at one end of the reflector 41 in the first direction d1 and the reflection electrode finger located at the other end thereof is defined as Dr. Then, the average arrangement pitch pr can be represented by an equation pr=Dr/(Nr−1). Incidentally, (Nr−1) may be conceived as a total number of gaps between adjoining reflection electrode fingers in the reflector 41. The average arrangement pitch pr of the reflection electrode fingers 45 of the reflector 42 is similarly derived as well.

Incidentally, as for measurement sites for the arrangement pitches, a distance between imaginary lines extending through midpoints of intersecting widths of specified adjoining electrode fingers with respect to the first direction d1 and being parallel to the second direction d2 may be substituted. In a method of measuring the arrangement pitches, measurements can be taken from length measurements based on observation by optical microscope or SEM from a top face (direction perpendicular to both of the first direction d1 and the second direction d2) or based on exposition of a section intersecting the imaginary lines by grinding or the like and observation by optical microscope or SEM.

### Bandpass Characteristics of Acoustic Wave Filter

Bandpass characteristics and the like of acoustic wave filters of working examples and comparative examples will be described.

FIG. 4 is a diagram illustrating an example of the average arrangement pitches px, py of the electrode fingers 35 of the first excitation portions 51x, 52x and the second excitation portions 51y, 52y and the average arrangement pitch pr of the reflection electrode fingers 45 of the reflectors 41, 42.

A vertical axis at left in FIG. 4 represents wavelengths that are double the arrangement pitches. Further, a vertical axis at right in FIG. 4 represents the numbers of pairs of the electrode fingers 35 and the reflection electrode fingers 45. Incidentally, the numbers of pairs in the reflectors 41, 42 are values obtained with two reflection electrode fingers 45 defined as a pair.

As illustrated in FIG. 4, the second excitation portion 51y is smaller in the average arrangement pitch px than the first excitation portion 51x and the second excitation portion 52y is smaller in the average arrangement pitch py than the first excitation portion 52x. Incidentally, the first excitation portion and the second excitation portion are equal in duty and are equal in the intersecting width.

Further, the second excitation portion 51y is smaller in the number of the pairs than the first excitation portion 51x and the second excitation portion 52y is smaller in the number of the pairs than the first excitation portion 52x. In other words, the number of the electrode fingers 35 in the first excitation portion 51x (or 52x) is greater than the number of the electrode fingers 35 in the second excitation portion 51y (or 52y). Incidentally, the numbers of pairs in the first excitation portions 51x and 52x are equal and the numbers of pairs in the second excitation portions 51y and 52y are equal.

Further, the reflector 41 is greater in the number of the pairs than the first excitation portion 51x and the reflector 42 is greater in the number of the pairs than the first excitation portion 52x. In this example, the number of the reflection electrode fingers 45 in the reflector 41 (or 42) is greater than the number of the electrode fingers 35 in the first excitation portion 51x (or 52x). Incidentally, the numbers of the pairs in the reflectors 41 and 42 are equal.

The bandpass characteristics with change in the arrangement pitch ratio (pr/px) under conditions of electrode parameters described above will be described.

Initially, excitation waves of resonant mode M1 that occur in a band on a lower frequency side relative to the pass band will be described.

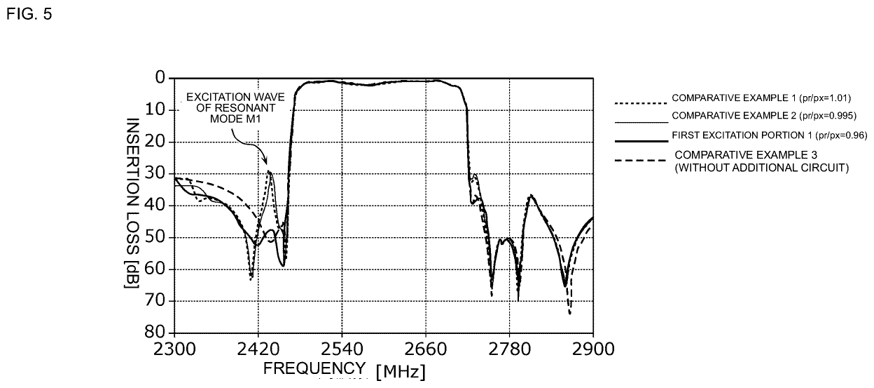

FIG. 5 is a diagram illustrating bandpass characteristics of acoustic wave filters of comparative examples 1, 2, and 3 and working example 1.

Comparative example 1 represents the bandpass characteristics with the arrangement pitch ratio (pr/px) of 1.01. Comparative example 2 represents the bandpass characteristics with the arrangement pitch ratio (pr/px) of 0.995. Comparative example 3 represents the bandpass characteristics only of a filter circuit provided with no additional circuit. Working example 1 represents the bandpass characteristics with the arrangement pitch ratio (pr/px) of 0.96.

As illustrated in FIG. 5, attenuation in frequencies from 2350 MHz to 2420 MHz can be increased in comparative examples 1 and 2 and working example 1 in which the additional circuit is connected to the filter circuit 10, compared with comparative example 3 provided with no additional circuit.

In comparative examples 1 and 2, however, excitation waves (responses) having a peak value exceeding 30 dB occur in a vicinity of 2450 MHz located on the lower frequency side relative to the pass band. The excitation waves are excitation waves of the resonant mode M1 that occur in a gap between the IDTs 31 and 32 of the acoustic coupling resonator 25.

In working example 1, in contrast to that, the excitation waves of the resonant mode M1 are reduced or prevented in a band (of 2420 MHz to 2490 MHz illustrated in FIG. 5) located on the lower frequency side relative to the pass band. According to the acoustic wave filter 1 of working example 1, attenuation can be ensured in the band located on the lower frequency side relative to the pass band.

In working example 1, further, occurrence of excitation waves can be reduced or prevented in a band (of 2720 MHz to 2740 MHz illustrated in FIG. 5) located on a higher frequency side relative to the pass band, compared with comparative examples 1 and 2. According to the acoustic wave filter 1 of working example 1, the attenuation can be ensured in the band located on the higher frequency side relative to the pass band as well.

Herein, a range of the arrangement pitch ratio (pr/px) suitable for reducing or preventing the excitation waves of the resonant mode M1 will be described.

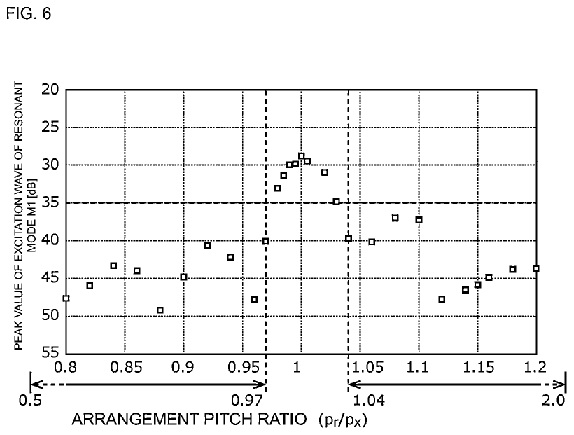

FIG. 6 is a diagram illustrating a relationship between arrangement pitch ratios (pr/px) that are ratios of the average arrangement pitch px of the electrode fingers 35 of the first excitation portions to the average arrangement pitch pr of the reflection electrode fingers 45 of the reflector and amplitudes of excitation waves of the resonant mode M1 that occur in a gap between the IDTs 31 and 32 of the acoustic coupling resonator 25. Incidentally, original data of a graph of FIG. 6 is as shown in Table 1.

TABLE 1

| Arrangement pitch | Peak value of excitation wave of |
|---|---|
| ratio (pr/px) | resonant mode M1 [dB] |
| 0.8 | 47.6 |
| 0.82 | 45.91 |
| 0.84 | 43.24 |
| 0.86 | 43.95 |
| 0.88 | 49.16 |
| 0.9 | 44.76 |
| 0.92 | 40.62 |
| 0.94 | 42.16 |
| 0.96 | 47.81 |
| 0.97 | 39.99 |
| 0.98 | 32.98 |
| 0.985 | 31.3 |
| 0.99 | 29.83 |
| 0.995 | 29.72 |
| 1.0 | 28.65 |
| 1.005 | 29.27 |
| 1.01 | 28.77 |
| 1.02 | 30.86 |
| 1.03 | 34.73 |
| 1.04 | 39.69 |
| 1.06 | 40.12 |
| 1.08 | 36.92 |
| 1.1 | 37.21 |
| 1.12 | 47.71 |
| 1.14 | 46.45 |
| 1.15 | 45.78 |
| 1.16 | 44.8 |
| 1.18 | 43.71 |
| 1.2 | 43.63 |

A vertical axis in FIG. 6 represents peak values of the excitation waves of the resonant mode M1 that occur in the gap between the IDTs 31 and 32. A horizontal axis in the same drawing represents the arrangement pitch ratios (pr/px) described above. Incidentally, the arrangement pitch ratio (pr/px) was changed in value with px fixed and with pr changed.

As for evaluation of the excitation waves of the resonant mode M1, it was determined in this example that the occurrence of the excitation waves was reduced or prevented, provided the peak value of the excitation waves was lower than or equal to about 35 dB, for example. Though it can be determined that the attenuation has been ensured when insertion loss is lower than or equal to 30 dB, for instance, 35 dB was used as an evaluation criterion in this example because the resonant mode M1 appears in the band near the pass band of the acoustic wave filter 1.

In the acoustic wave filter 1, as illustrated in FIG. 6, the peak value of the excitation waves of the resonant mode M1 can be made lower than about 35 dB on condition that the arrangement pitch (pr/px) has a value in the range from about 0.5 to about 0.97 or a range from about 1.04 to about 2.0, for example.

Incidentally, a lower limit of the arrangement pitch ratio (pr/px) that is greater than or equal to about 0.5 and an upper limit thereof that is smaller than or equal to about 2.0 are preferable because the arrangement pitch ratio (pr/px) smaller than about 0.5 or greater than about 2.0 prevents coupling of the reflectors and waves having occurred in the IDTs and inhibits fulfilment of a role of the reflectors in preventing acoustic coupling with other resonators.

Subsequently, excitation waves of resonant mode M2 that occur in a band on a lower frequency side relative to the resonant mode M1 will be described.

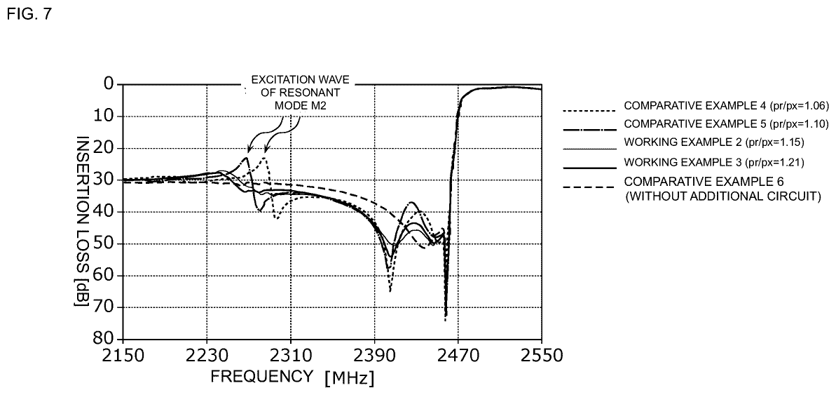

FIG. 7 is a diagram illustrating bandpass characteristics of acoustic wave filters of comparative examples 4, 5, and 6 and working examples 2 and 3. In the drawing, bandpass characteristics in a portion of the pass band of the acoustic wave filter and on the lower frequency side relative to the pass band are illustrated.

Comparative example 4 represents the bandpass characteristics with the arrangement pitch ratio (pr/px) of 1.06. Comparative example 5 represents the bandpass characteristics with the arrangement pitch ratio (pr/px) of 1.10. Comparative example 6 represents the bandpass characteristics only of a filter circuit provided with no additional circuit. Incidentally, comparative example 6 is the same as comparative example 3 described above. Working example 2 represents the bandpass characteristics with the arrangement pitch ratio (pr/px) of 1.15. Working example 3 represents the bandpass characteristics with the arrangement pitch ratio (pr/px) of 1.21.

As illustrated in FIG. 7, attenuation in frequencies from 2310 MHz to 2390 MHz can be increased in comparative examples 4 and 5 and working examples 2 and 3 in which the additional circuit is connected to the filter circuit 10, compared with comparative example 6 provided with no additional circuit.

In comparative examples 4 and 5, however, excitation waves (responses) having a peak value exceeding 25 dB occur in a band of 2250 MHz to 2290 MHz located on the lower frequency side relative to the pass band. The excitation waves are excitation waves of the resonant mode M2 that occur due to acoustic coupling in the acoustic coupling resonator.

In working examples 2 and 3, in contrast to that, the excitation waves of the resonant mode M2 are reduced or prevented in a band (in a vicinity of 2230 MHz illustrated in FIG. 7) located on the lower frequency side relative to the pass band. According to the acoustic wave filter 1 of working examples 2 and 3, attenuation can be ensured in the band located on the lower frequency side relative to the pass band.

Herein, a range of the arrangement pitch ratio (pr/px) suitable for reducing or preventing the excitation waves of the resonant mode M2 will be described.

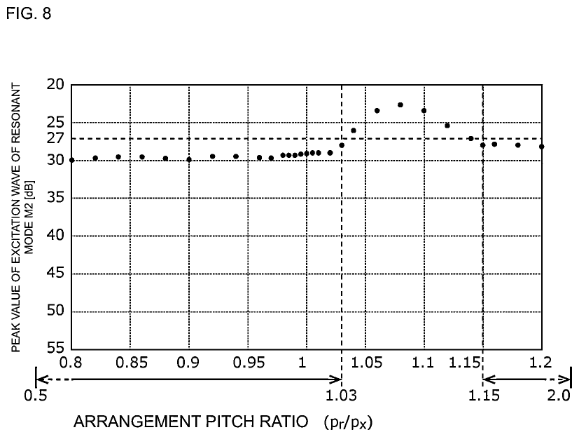

FIG. 8 is a diagram illustrating a relationship between the arrangement pitch ratios (pr/px) that are the ratios of the average arrangement pitch px of the electrode fingers 35 of the first excitation portions to the average arrangement pitch pr of the reflection electrode fingers 45 of the reflectors and amplitudes of excitation waves of the resonant mode M2 that occur due to acoustic coupling in the acoustic coupling resonator 25. Incidentally, original data of a graph of FIG. 8 is as shown in Table 2.

TABLE 2

| Arrangement pitch | Peak value of excitation wave of |
|---|---|
| ratio (pr/px) | resonant mode M2 [dB] |
| 0.8 | 29.77 |
| 0.82 | 29.56 |
| 0.84 | 29.37 |
| 0.86 | 29.4 |
| 0.88 | 29.6 |
| 0.9 | 29.75 |
| 0.92 | 29.33 |
| 0.94 | 29.3 |
| 0.96 | 29.51 |
| 0.97 | 29.55 |
| 0.98 | 29.16 |
| 0.985 | 29.14 |
| 0.99 | 29.18 |
| 0.995 | 29.03 |
| 1.0 | 28.93 |
| 1.005 | 28.87 |
| 1.01 | 28.84 |
| 1.02 | 28.84 |
| 1.03 | 27.84 |
| 1.04 | 25.9 |
| 1.06 | 23.27 |
| 1.08 | 22.49 |
| 1.1 | 23.27 |
| 1.12 | 25.25 |
| 1.14 | 26.95 |
| 1.15 | 27.85 |
| 1.16 | 27.71 |
| 1.18 | 27.85 |
| 1.2 | 28.03 |

A vertical axis in FIG. 8 represents peak values of the excitation waves of the resonant mode M2 that occur due to the acoustic coupling in the acoustic coupling resonator 25. A horizontal axis in the same drawing represents the arrangement pitch ratios (pr/px) described above. Incidentally, the arrangement pitch ratio (pr/px) was changed in value with px fixed and with pr changed.

As for evaluation of the excitation waves of the resonant mode M2, it was determined in this example that the occurrence of the excitation waves was reduced or prevented, provided the peak value of the excitation waves was lower than or equal to about 27 dB, for example. The resonant mode M2 is in a distant location from the pass band and thus 27 dB was used as an evaluation criterion in this example, though it can be determined that the attenuation has been ensured when the insertion loss is lower than or equal to 25 dB, for instance.

In the acoustic wave filter 1, as illustrated in FIG. 8, the peak value of the excitation waves of the resonant mode M2 can be made lower than 27 dB on condition that the arrangement pitch (pr/px) has a value in the range from 0.5 to 1.03 or a range from 1.15 to 2.0 inclusive.

Incidentally, a lower limit of the arrangement pitch ratio (pr/px) that is greater than or equal to about 0.5 and an upper limit thereof that is smaller than or equal to about 2.0 are preferable because the arrangement pitch ratio (pr/px) smaller than about 0.5 or greater than about 2.0 prevents coupling of the reflectors and waves having occurred in the IDTs and inhibits fulfilment of a role of the reflectors in preventing acoustic coupling with other resonators.

Based on FIGS. 6 and 8 described above, furthermore, it is conceived that the arrangement pitch ratio (pr/px) is preferably set as follows in order to reduce or prevent the excitation waves of both the resonant modes M1 and M2. Specifically, the excitation waves of both the resonant modes M1 and M2 can be reduced or prevented by setting of the arrangement pitch ratio (pr/px) in the range from about 0.5 to about 0.97 or the range from about 1.15 to about 2.0 such that both the ranges in FIGS. 6 and 8 are satisfied. Thus, the occurrence of the excitation waves in the bands out of the pass band can be reduced or prevented.

### Overview

The acoustic wave filter 1 according to the present example embodiment can assume aspects that will be described below.

### Aspect 1

The acoustic wave filter 1 according to the present example embodiment includes the plurality of input-output terminals T1, T2, the filter circuit 10 in the first path r1 linking the plurality of input-output terminals T1, T2; and the additional circuit 20 in the second path r2 connected in parallel to at least a portion of the first path r1. The additional circuit 20 includes the resonator (the acoustic coupling resonator 25, for instance) including the plurality of IDTs 31, 32 and the reflector 41. The plurality of IDTs 31, 32 are located along the first direction d1. The IDTs 31, 32 each include the plurality of electrode fingers 35 extending in the second direction d2 intersecting with the first direction d1 and arranged along the first direction d1. The reflector 41 is located adjacent to the outermost IDT 31 that is located in the outermost side portion of the plurality of IDTs 31, 32 with respect to the first direction d1 and includes the plurality of reflection electrode fingers 45 extending in the second direction d2 and arranged along the first direction d1. The outermost IDT 31 includes the first excitation portion 51x and the second excitation portion 51y. The first excitation portion 51x is located adjacent to the reflector 41 in the first direction d1 and, assuming the total number of the plurality of electrode fingers 35 included in the outermost IDT 31 is defined as N, the first excitation portion 51 includes ((N/2)+1) number of electrode fingers when N is an even number or the first excitation portion 51 includes ((N+1)/2) number of electrode fingers when N is an odd number. The second excitation portion 51y is located on the opposite side to the reflector 41 as seen from the first excitation portion 51x in the first direction d1 and includes two or more electrode fingers, except the electrode fingers of the first excitation portion 51x, among the plurality of electrode fingers 35 included in the outermost IDT 31. Assuming the average arrangement pitch of the electrode fingers included in the first excitation portion 51x in the first direction d1 is defined as px and assuming the average arrangement pitch of the plurality of reflection electrode fingers 45 in the first direction d1 is defined as pr, pr/px has a value in the range from about 0.5 to about 0.97 or the range from about 1.15 to about 2.0.

Thus, the occurrence of the excitation waves of the resonant modes M1, M2 in the bands out of the pass band of the acoustic wave filter 1 can be reduced or prevented by setting of pr/px that is the ratio of the average arrangement pitches in the range from about 0.5 to about 0.97 or the range from about 1.15 to about 2.0. As a result, the attenuation characteristics in the bands out of the pass band can be ensured.

Incidentally, the same thing can be said of aspect 1 with replacement of the reflector 41 by the reflector 42, replacement of the outermost IDT 31 by the outermost IDT 32, replacement of the first excitation portion 51x by the first excitation portion 52x, and replacement of the second excitation portion 51y by the second excitation portion 52y.

### Aspect 2

In the acoustic wave filter 1 described as aspect 1, assuming an average arrangement pitch of the electrode fingers included in the second excitation portion 51y in the first direction d1 is defined as py, px>py is satisfied.

By this configuration, the arrangement pitch of the electrode fingers 35 of the second excitation portion 51y can be made narrower than the arrangement pitch of the electrode fingers 35 of the first excitation portion 51x and the occurrence of the excitation waves of the resonant mode M1 can be reduced or prevented. As a result, the attenuation characteristics in the bands out of the pass band can be ensured.

### Aspect 3

In the acoustic wave filter 1 described as aspect 1 or 2, the additional circuit 20 may include the plurality of reflectors 41, 42, and the plurality of reflectors 41, 42 may be located at outer side portions out of the plurality of IDTs 31, 32 with respect to the first direction d1.

By this configuration, Q-value can be improved by inclusion of the plurality of reflectors 41, 42. Further, even if the plurality of reflectors 41, 42 are used, the occurrence of the excitation waves of the resonant modes M1, M2 can be reduced or prevented by setting of pr/px at a value in the range described above. As a result, the attenuation characteristics in the bands out of the pass band can be ensured.

### Aspect 4

In the acoustic wave filter 1 described as any one of aspects 1 to 3, a pass band of the filter circuit 10 may include a frequency band from about 2496 MHz to about 2690 MHz.

By this configuration, the occurrence of the excitation waves of the resonant modes M1, M2 in bands out of a range of the frequency band can be reduced or prevented. As a result, the attenuation characteristics in the bands out of the pass band can be ensured.

### OTHER EXAMPLE EMBODIMENTS

Though the acoustic wave filters according to example embodiments of the present invention have been described above, other example embodiments that are implemented with combination of elements, components, features, characteristics, etc., of the above example embodiment, modifications obtained with various modifications to the present example embodiment, and multiplexers, high-frequency front-end circuits, and communication devices including the acoustic wave filter according to example embodiments of the present invention are also encompassed by the present invention.

Though the examples in which the acoustic coupling resonator 25 includes the two IDTs 31, 32 have been described above, there is no limitation thereto and the acoustic coupling resonator 25 may include three or more IDTs. Even if the acoustic coupling resonator 25 includes three or more IDTs, the IDTs 31, 32 become the outermost IDTs and the arrangement pitch ratio (pr/px) has a value in similar ranges.

Though the examples in which the IDTs 31, 32 are directly connected to the nodes n1, n8 on the first path r1 have been described above, there is no limitation thereto and the IDTs 31, 32 may be connected to the nodes n1, n8 with capacitance elements interposed therebetween.

Though the examples in which the acoustic wave filter 1 is a transmitting and receiving filter have been described above, there is no limitation thereto and the acoustic wave filter 1 may be a transmitting filter or a receiving filter.

Further, the input-output terminals T1 and T2 each may be either an input terminal or an output terminal. For instance, the input-output terminal 12 becomes an output terminal in case where the input-output terminal T1 is an input terminal or the input-output terminal T1 becomes an output terminal in case where the input-output terminal 12 is an input terminal.

Further, the IDT electrodes do not have to have the stacked structure. The IDT electrodes may be made of metals such as Ti, Al, Cu, Pt, Au, Ag, or Pd or alloy, for instance, and may be made of a plurality of multilayer bodies made of the metals or the alloy.

Further, though the substrate having piezoelectricity has been described as a substrate in the example embodiment, the substrate may be a piezoelectric substrate made of a single layer of a piezoelectric layer. The piezoelectric substrate in this configuration is made of piezoelectric single crystal of LiTaO₃ or another piezoelectric single crystal of LiNbO₃ or the like, for instance. Further, a structure in which a piezoelectric layer is stacked on a support substrate, instead of a substrate made of a piezoelectric layer as a whole, may be used as the substrate on which the IDT electrodes are formed, as long as piezoelectricity is provided therefor. Further, there is no limitation to a cut-angle of the substrate according to the example embodiments. That is, the stacked material, and thicknesses may be appropriately modified in accordance with required bandpass characteristics or the like of the acoustic wave filter and similar effects can be fulfilled even by a surface acoustic wave filter with use of a LiTaO₃ piezoelectric substrate, a LiNbO₃ piezoelectric substrate, or the like that has a cut-angle other than the cut-angle specified in the example embodiment.

Incidentally, the additional circuit 20 may include a transversal type acoustic wave resonator instead of an acoustic coupling type acoustic wave resonator.

Example embodiments of the present invention can be broadly utilized as multiplexers, front-end circuits, and communication devices each including the acoustic wave filter for communications equipment such as cellular phone.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave filter comprising:
a plurality of input-output terminals;
a filter circuit in a first path linking the plurality of input-output terminals; and
an additional circuit in a second path connected in parallel to at least a portion of the first path; wherein
the additional circuit includes a resonator including a plurality of interdigital transducers (IDTs) and a reflector;
the plurality of IDTs are arranged along a first direction;
the IDTs each include a plurality of electrode fingers extending in a second direction intersecting with the first direction and arranged along the first direction;
the reflector is adjacent to an outermost IDT that is located in an outermost side portion of the plurality of IDTs with respect to the first direction and includes a plurality of reflection electrode fingers extending in the second direction and arranged along the first direction;
the outermost IDT includes a first excitation portion and a second excitation portion;
the first excitation portion is adjacent to the reflector in the first direction;
the outermost IDT includes ((N/2)+1) electrode fingers when a total number N of the electrode fingers included in the outermost IDT is an even number, or the outermost IDT includes ((N+1)/2) electrode fingers when the total number N is an odd number;
the second excitation portion is on an opposite side to the reflector as seen from the first excitation portion in the first direction and includes two or more electrode fingers, except the electrode fingers of the first excitation portion, among the plurality of electrode fingers included in the outermost IDT; and
assuming an average arrangement pitch of the electrode fingers included in the first excitation portion in the first direction is px and an average arrangement pitch of the plurality of reflection electrode fingers in the first direction is pr, pr/px has a value in a range from about 0.5 to about 0.97 or a range from about 1.15 to about 2.0.

2. The acoustic wave filter according to claim 1, wherein, assuming an average arrangement pitch of the electrode fingers included in the second excitation portion in the first direction is defined as py, px>py is satisfied.

3. The acoustic wave filter according to claim 1, wherein the additional circuit includes a plurality of reflectors at outer side portions of the plurality of IDTs with respect to the first direction.

4. The acoustic wave filter according to claim 1, wherein a pass band of the filter circuit includes a frequency band from about 2496 MHz to about 2690 MHz.

5. The acoustic wave filter according to claim 1, wherein the filter circuit has a ladder filter structure.

6. The acoustic wave filter according to claim 1, wherein the filter circuit includes a plurality of serial arm resonators on the first path and a plurality of parallel arm resonators on paths linking the first path and a ground.

7. The acoustic wave filter according to claim 1, wherein the resonator included in the additional circuit is an acoustic coupling resonator.

8. The acoustic wave filter according to claim 1, wherein the resonator included in the additional circuit is a surface acoustic wave resonator.

9. The acoustic wave filter according to claim 1, wherein the resonator included in the additional circuit includes a piezoelectric substrate on which the plurality of IDTs and the reflector are provided.

10. The acoustic wave filter according to claim 9, wherein the piezoelectric substrate includes SiN, SiO₂, and LiTaO₃ stacked in order on a silicon substrate.

11. The acoustic wave filter according to claim 1, wherein the resonator included in the additional circuit includes a dielectric layer on the plurality of IDTs and the reflector.

12. The acoustic wave filter according to claim 1, wherein the first excitation portion is structured to generate a cancellation component having an opposite phase to and a same amplitude as those of the filter circuit.

13. The acoustic wave filter according to claim 1, wherein the second excitation portion is structured to reduce excitation of the first excitation portion.

14. The acoustic wave filter according to claim 1, wherein arrangement pitches of the plurality of reflection electrode fingers in the first direction are identical.

15. The acoustic wave filter according to claim 1, wherein at least some of arrangement pitches of the plurality of reflection electrode fingers in the first direction are different.

16. The acoustic wave filter according to claim 1, wherein the first excitation portion and the second excitation portion are equal in duty and are equal in an intersecting width.

17. The acoustic wave filter according to claim 7, wherein the acoustic coupling resonator includes two IDTs.

18. The acoustic wave filter according to claim 7, wherein the acoustic coupling resonator includes three or more IDTs.

19. The acoustic wave filter according to claim 1, wherein the acoustic wave filter is a transmitting and receiving filter.

20. The acoustic wave filter according to claim 1, wherein the acoustic wave filter is a transmitting filter or a receiving filter.
